(19) United States
(12) Patent Application Publication
(10) Pub. No.: US 2024/0306481 A1
(43) Pub. Date: Sep. 12, 2024

(54) METHOD OF MANUFACTURING LIGHT EMITTING DIODE

(71) Applicant: Samsung Display Co., LTD., Yongin-si (KR)

(72) Inventor: SOOHYUN PARK, Yongin-si (KR)

(21) Appl. No.: 18/500,042

(22) Filed: Nov. 1, 2023

(30) Foreign Application Priority Data
Mar. 8, 2023 (KR) 10-2023-0030550

(51) Int. Cl. H10K 71/13; H10K 50/115; H10K 71/40; H10K 71/60

(52) U.S. Cl. CPC H10K 71/135; H10K 50/115; H10K 71/40; H10K 71/60

(57) ABSTRACT

A light emitting diode is manufactured by forming a first auxiliary layer on a substrate, providing a first emission solution including a quantum dot on the first auxiliary layer, heating the first emission solution to a first temperature to form a second emission solution, forming an emission layer by heating the second emission solution to a second temperature less than the first temperature, and forming a second auxiliary layer on the emission layer.

### CROSS-REFERENCED TO RELATED APPLICATION

This application claims priority to and the benefit of Korean Patent Application No. 10-2023-0030550, filed on Mar. 8, 2023, in the Korean Intellectual Property Office, the content of which in its entirety is herein incorporated by reference.

### BACKGROUND

### 1. Field

Embodiments of the present disclosure relate generally to a method of manufacturing a light emitting diode.

### 2. Description of the Related Art

A display device is a device that displays images, and examples of the display device include an organic light emitting display device and a liquid crystal display device. An organic light emitting display device includes an organic emission layer interposed between a pixel electrode and a common electrode. When the two electrodes respectively inject electrons and holes into the organic emission layer, light is emitted according to the combination of electrons and holes.

The organic light emitting diode display includes red, green, and blue subpixels, and an organic emission layer that emits light is formed in each subpixel. In addition, in order to improve the light emitting efficiency of the organic emission layer, at least one common layer (e.g., a hole transport layer, an electron transport layer, etc.) is further on and/or below the organic emission layer.

In the process of forming the organic emission layer and the common layer, it is desirable or necessary that a lower layer is not damaged by an upper layer during formation of the upper layer.

### SUMMARY

Embodiments of the present disclosure provide a method of manufacturing a light emitting diode.

A method of manufacturing a light emitting diode according to an embodiment may include forming a first auxiliary layer on a substrate, providing a first emission solution including a quantum dot on the first auxiliary layer, forming a second emission solution by heating the first emission solution to a first temperature, forming an emission layer by heating the second emission solution to a second temperature lower than the first temperature, and forming a second auxiliary layer on the emission layer.

In an embodiment, the second emission solution may be annealed at the second temperature.

In an embodiment, the first temperature may be greater than 200° C. and less than 250° C., and the second temperature may be about 70° C. or more and 200° C. or less.

In an embodiment, the first emission solution may be heated in a nitrous oxide (N₂O) environment, and the second emission solution may be heated in an air environment.

In an embodiment, the air environment may include moisture and/or oxygen.

In an embodiment, the first emission solution may be heated for about 10 minutes to 30 minutes, and the second emission solution may be heated for about 5 minutes to 20 minutes.

In an embodiment, the quantum dot may include nanoparticles, and each of the nanoparticles may include a core including a first semiconductor material and a shell including a second semiconductor material.

In an embodiment, the first semiconductor material and the second semiconductor material may each independently include at least one selected from the group consisting of InP, ZnSe, and ZnS.

In an embodiment, the forming the first auxiliary layer may include forming an electron injection layer on the substrate and forming an electron transport layer on the electron injection layer.

In an embodiment, the forming the second auxiliary layer may include forming a hole transport layer on the emission layer and forming a hole injection layer on the hole transport layer.

In an embodiment, the method may further include forming a cathode on the substrate; and forming an anode on the second auxiliary layer.

In an embodiment, the method may further include forming a capping layer on the anode.

In an embodiment, the first emission solution may be provided through an inkjet printing method.

A method of manufacturing a light emitting diode according to another embodiment may include forming a first auxiliary layer on a substrate, providing a first emission solution including a quantum dot on the first auxiliary layer, forming a second emission solution by heating the first emission solution, forming an emission layer by heating the second emission solution in an air environment, and forming a second auxiliary layer on the emission layer.

In an embodiment, the second emission solution may be annealed in the air environment.

In an embodiment, the first emission solution may be heated in a nitrous oxide (N₂O) environment, and the air environment may include moisture and oxygen.

In an embodiment, the first emission solution may be heated to a first temperature, and the second emission solution may be heated a second temperature lower than the first temperature.

A method of manufacturing a light emitting diode according to still another embodiment may include forming a first auxiliary layer on a substrate, providing an emission solution including a quantum dot on the first auxiliary layer, forming an emission layer by heating the emission solution in an air environment, and forming a second auxiliary layer on the emission layer.

In an embodiment, the air environment may include moisture and oxygen.

In an embodiment, the emission solution may be heated for about 5 minutes to 20 minutes at about 70° C. or more and 200° C. or less.

Therefore, in the method of manufacturing a light emitting diode according to an embodiment of the present disclosure, a second emission solution may be formed by baking the first emission solution, and the emission layer may be formed by annealing the second emission solution. The first emission solution may be heated in a nitrous oxide (N₂O) environment at a first temperature of greater than about 200° C. and less than about 250° C., for about 10 minutes to about 30 minutes. The second emission solution may be heated at a second temperature of about 70° C. or more and about 200° C., for about 5 minutes to about 20 minutes in an air environment including moisture and oxygen. An environment and the second temperature in which the second emission solution is annealed may be different from an environment and a first temperature in which the first emission solution is baked, respectively. For example, the second emission solution may be heated in an air environment, and the second temperature may be lower than the first temperature.

As the second emission solution is annealed in a relatively mild environment, a film density of the emission layer may increase. Accordingly, during the formation of the hole transport layer, defects in film cracking and/or film tearing of the light emitting layer may be prevented or reduced.

### BRIEF DESCRIPTION OF THE DRAWINGS

The accompanying drawings, which are included to provide a further understanding of the subject matter of the present disclosure and are incorporated in and constitute a part of this specification, illustrate embodiments of the present disclosure together with the description.

FIG. 1 is a cross-sectional view illustrating a light emitting diode according to an embodiment of the present invention.

FIG. 2 is a flowchart illustrating an example of a method of manufacturing the light emitting diode of FIG. 1.

FIGS. 3, 4, 5, 6, 7, 8, and 9 are cross-sectional views illustrating the method of FIG. 2.

FIG. 10 is a flowchart illustrating another example of a method of manufacturing the light emitting diode of FIG. 1.

FIG. 11 is a diagram illustrating micrographs of the light emitting diode according to a comparative embodiment and embodiments of the present invention.

### DETAILED DESCRIPTION

Illustrative, non-limiting embodiments will be more clearly understood from the following detailed description in conjunction with the accompanying drawings.

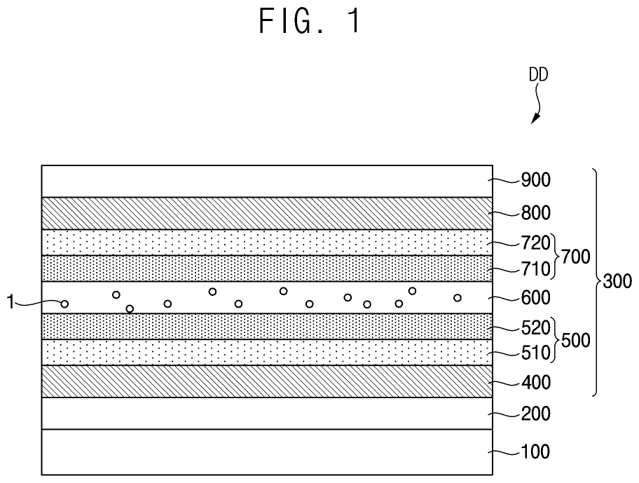

FIG. 1 is a cross-sectional view illustrating a light emitting diode according to an embodiment of the present invention.

Referring to FIG. 1, a display device DD according to an embodiment may include a substrate 100, a transistor layer 200, and a light emitting diode 300. The light emitting diode 300 may include a cathode 400, a first auxiliary layer 500, an emission layer 600, a second auxiliary layer 700, an anode 800, and a capping layer 900. The first auxiliary layer 500 may include an electron injection layer 510 and an electron transport layer 520, and the second auxiliary layer 700 may include a hole transport layer 710 and a hole injection layer 720.

The substrate 100 may be formed of glass, quartz, plastic, and/or the like. Examples of materials that can be used as the plastic may include polyimide (PI), polyacrylate, polymethylmethacrylate (PMMA), polycarbonate (PC), polyethylenenaphthalate (PEN), polyvinylidene chloride, polyvinylidene difluoride (PVDF), polystyrene, ethylene-vinyl alcohol copolymer, polyethersulphone (PES), poly etherimide (PEI), polyphenylene sulfide (PPS), polyallylate, tri-acetyl cellulose (TAC), cellulose acetate propionate (CAP), etc. These may be used alone or in combination with each other.

The transistor layer 200 may be on the substrate 100. A plurality of transistors may be on the transistor layer 200, and the transistors may generate driving current and may transfer the driving current to the cathode 400.

The cathode 400 may be on the transistor layer 200. In an embodiment, the cathode 400 may include a metal, an alloy, a metal oxide, a reflective conductive material (e.g., a reflective, electrically conductive material), and/or the like. Examples of materials that can be used as the anode 400 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other.

The electron injection layer 510 may be on the cathode 400. In an embodiment, the electron injection layer 510 may include an electron injection material. Examples of materials that can be used as the electron injection layer 510 may include metal halides such as LiF, NaCl, CsF, RbCl, and RbI, lanthanide metals such as Yb, metal oxides such as LiO and BaO, lithium quinolate (LiQ), and the like.

The electron transport layer 520 may be on the electron injection layer 510. In an embodiment, the electron transport layer 520 may include an electron transport material. Examples of materials that can be used as the electron transport layer 520 may include 8-Hydroxyquinolinolato-lithium (LiQ), Alq3 (tris (8-hydroxyquinolino) aluminum), and PBD (2-(4-biphenylyl)-5-(4-tert)-butylpheny)-1,3,4oxadiazole), TAZ, and spiro-PBD. These may be used alone or in combination with each other.

The emission layer 600 may be on the electron transport layer 520. When electrons and holes are injected into the emission layer 600, the emission layer 600 may emit light of a set or predetermined color. For example, the emission layer 600 may emit red, green, or blue light.

In an embodiment, the emission layer 600 may include a quantum dot (QD) 1. The quantum dot 1 may include nanoparticles, and each of the nanoparticles may have a core-shell structure including a core and a shell.

For example, each of the nanoparticles may include a core including a first semiconductor material and a shell including a second semiconductor material. The first semiconductor material and the second semiconductor material may each include independently ZnS, ZnSe, ZnTe, ZnO, MgSe, MgS, ZnSeS, ZnSeTe, ZnSTe, MgZnSe, MgZnS, CdZnSeS, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP, TiO, GaO, GaS, GaSe, GaSe, GaTe, InS, InSe, In2S3, In2Se3, InTe, InGaS3, InGaSe3, AgInS, AgInS2, CuInS, CuInS2, CuGaO2, AgGaO2, AgAlO2, AgInZnS, SrSe, SnS, SnSe, SnTe, PbS, PbSe, PbTe. SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe, and/or the like. For example, the first semiconductor material and the second semiconductor material may each independently include InP, ZnSe, and/or ZnS.

In addition, the emission layer 600 may further include an organic material, an organometallic compound, and/or the like.

The hole transport layer 710 may be on the emission layer 600. In an embodiment, the hole transport layer 710 may include a hole transport material. Examples of materials that can be used as the hole transport layer 710 may include HATCN (1,4,5,8,9,11-hexaazatriphenylene-hexanitrile), CuPc (cupper phthalocyanine), PEDOT (poly (3,4)-ethylenedioxythiophene), PANI (polyaniline), NPD (N, N-dinaphthyl-N, N′-diphenylbenzidine), and the like. These may be used alone or in combination with each other.

The hole injection layer 720 may be on the hole transport layer 710. In an embodiment, the hole injection layer 720 may include a hole injection material. Examples of materials that can be used as the hole injection layer 720 may include a phthalocyanine compound, DNTPD (N,N′-diphenyl-N,N′-bis-[4-(phenyl-m-tolyl-amino)-phenyl]-biphenyl-4,4′-diamine), m-MTDATA (4,4′,4″-[tris (3-methylphenyl)phenylamino] triphenylamine), TDATA (4,4′4″-tris (N, N-diphenylamino) triphenylamine), PEDOT/PSS, PANI/DBSA (polyaniline/dodecylbenzenesulfonic acid), PANI (polyaniline), NPD (N,N-dinaphthyl-N,N′-diphenylbenzidine), HATCN (1,4,5, 8,9,11-hexaazatriphenylene-hexanitrile) and the like.

The anode 800 may be on the hole injection layer 720. In an embodiment, the anode 800 may include of a metal, an alloy, a metal oxide, a reflective conductive material (e.g., a reflective electrically conductive material), and/or the like. Examples of materials that can be used as the anode 800 may include AgMg, silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other.

In an embodiment, the light emitting diode 300 may have an inverted structure. In other words, the cathode 400 on the substrate 100 may include a metal oxide (e.g., ITO), and the anode 800 disposed on the cathode 400 may include a metal having a relatively high work function. (e.g., AgMg). In addition, the light emitting diode 300 may further include a charge generation layer (CGL).

The capping layer 900 may be on the anode 800. The capping layer 900 may resonate light emitted from the emission layer 600 and may improve light extraction efficiency of the emission layer 600. For example, the capping layer 900 may include an organic material and/or an inorganic material.

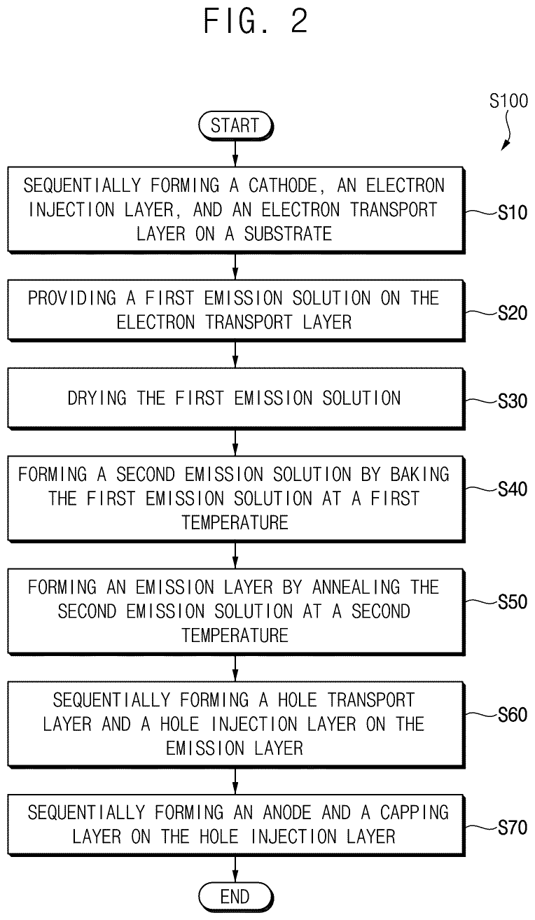

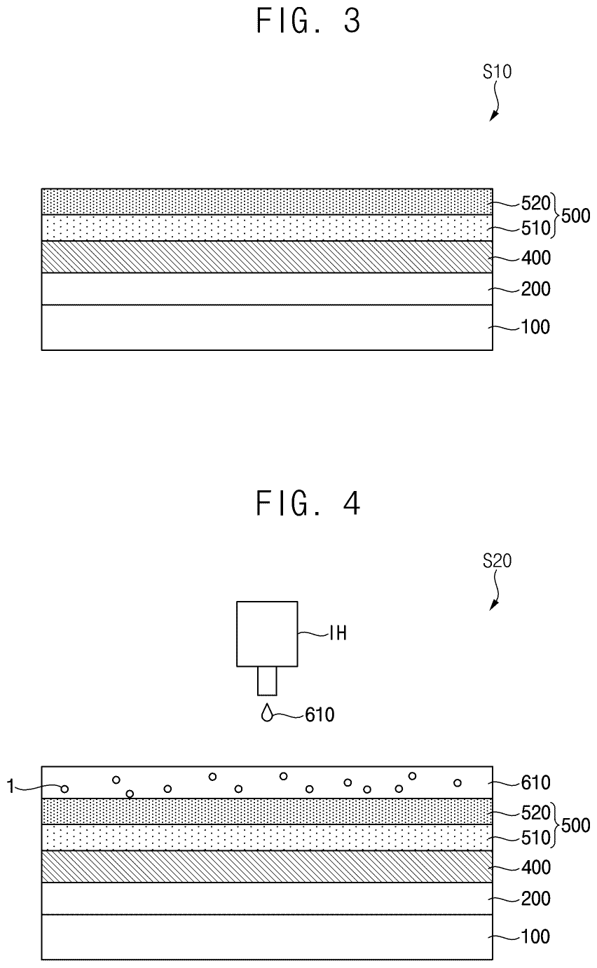

FIG. 2 is a flowchart illustrating an example of a method of manufacturing the light emitting diode of FIG. 1. FIGS. 3, 4, 5, 6, 7, 8, and 9 are cross-sectional views illustrating the method of FIG. 2.

Referring to FIGS. 1 and 2, in an example of a method of manufacturing the light emitting diode of FIG. 1 (S100), the cathode 400, the electron injection layer 510, and the electron transport layer 520 may be sequentially formed on the substrate 100 (S10). A first emission solution may be provided on the electron transport layer 520 (S20), the first emission solution may be dried (S30), and a second emission solution may be formed by baking the first emission solution at a first temperature (S40). The emission layer 600 may be formed by annealing the second emission solution at a second temperature (S50), and the hole transport layer 710 and the hole injection layer 720 may be sequentially formed on the emission layer 600 (S60). The anode 800 and the capping layer 900 may be formed on the hole injection layer 720 (S70).

In detail, referring to FIGS. 2 and 3, the cathode 400, the electron injection layer 510, and the electron transport layer 520 may be sequentially formed on the substrate 100 (S10). The electron injection layer 510 and the electron transport layer 520 may be formed through various suitable processes such as inkjet printing, vacuum deposition, spin coating, casting, LB (Langmuir-Blodgett), laser printing, and/or laser induced thermal imaging (LITI).

Referring to FIGS. 2 and 4, a first emission solution 610 may be provided on the electron transport layer 520 (S20). The first emission solution 610 may be provided through various suitable processes such as inkjet printing method, vacuum deposition method, spin coating method, cast method, LB method (Langmuir-Blodgett), laser printing method, and/or laser induced thermal imaging (LITI). In an embodiment, the first emission solution 610 may be provided through an inkjet printing method using an inkjet head (IH).

The first emission solution 610 may include the quantum dot 1, a solvent, and a polymerization initiator.

The solvent may be a solvent capable of properly dispersing the quantum dot 1, and for example, may be a hydrophilic solvent. When the solvent is a hydrophilic solvent, the solvent may be an alcohol-based solvent such as an aliphatic alcohol, an aromatic alcohol, and/or a polyhydric alcohol. In more detail, the solvent may be a solvent such as methanol, ethanol, phenol, benzenediol, ethylene glycol, glycerol, diethylene glycol, triethylene glycol, ethylene glycol monoethyl ether, and/or ethylene glycol monobutyl ether.

The polymerization initiator may include a thermal polymerization initiator capable of forming radicals by heat and/or a photopolymerization initiator capable of forming radicals by light.

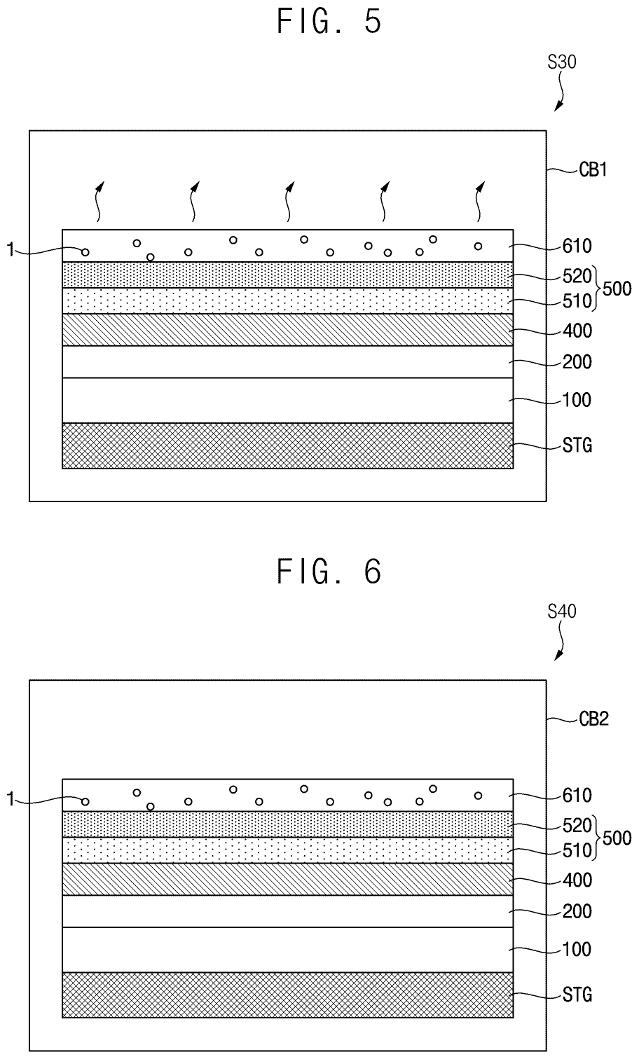

Referring to FIGS. 2 and 5, the first emission solution 610 may be dried (S30). In an embodiment, the first emission solution 610 may be dried at about 100° C. or less in a first chamber CB1 in a high vacuum environment, and the solvent included in the first emission solution 610 may be removed.

Referring to FIGS. 2 and 6, a second emission solution 620 may be formed by baking the first emission solution 610 at a first temperature (S40). In more detail, the first emission solution 610 may be heated to the first temperature in a second chamber CB2 in a nitrous oxide (N₂O) environment, and the solvent remaining in the first emission solution 610 may be removed. The second chamber CB2 may be the same as or different from the first chamber CB1, the first temperature may be about 100° C. to 250° C., and may be heated for about 10 minutes to 30 minutes. In an embodiment, preferably, the first temperature may be greater than about 200° C. and less than 250° C.

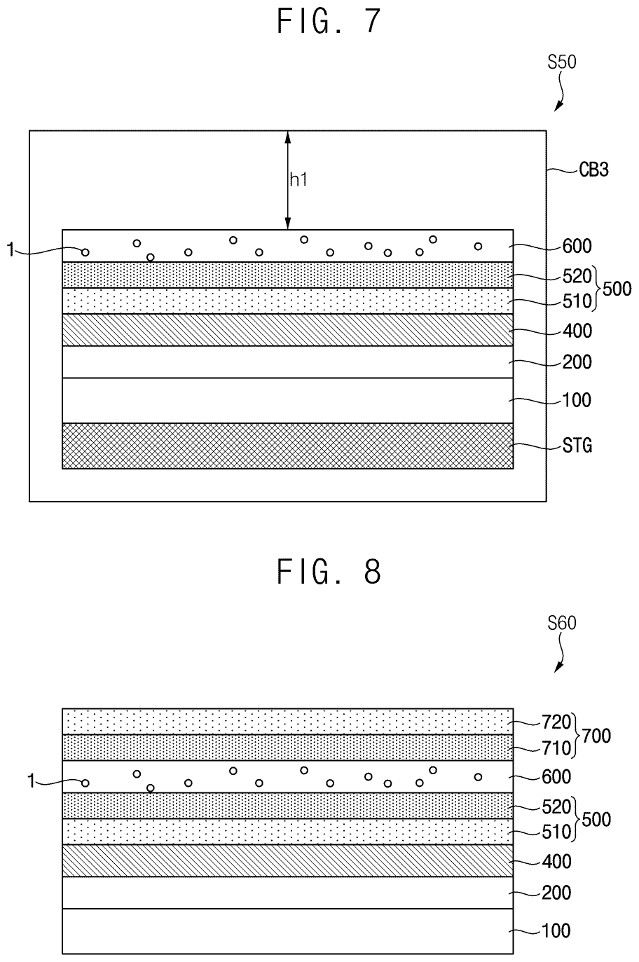

Referring to FIGS. 2 and 7, the emission layer 600 may be formed by annealing the second emission solution 620 at a second temperature (S50). In more detail, the substrate 100 on which the second emission solution 620 is formed may be loaded into a third chamber CB3 at a pin-up height, and may be annealed at a pin-down height h1 (e.g., about 9 mm) by the stage STG. The second emission solution 620 may be heated to the second temperature in the third chamber CB3 in an air environment including moisture and oxygen, and the film density of the second emission solution 620 may be increased. The third chamber CB3 may be the same as or different from the second chamber CB2, the second temperature may be about 70° C. to 200° C., and may be heated for about 5 minutes to 20 minutes. In addition, the second emission solution 620 may be cooled after the heating process is finished.

In an embodiment, the second temperature may be lower than the first temperature. For example, the first temperature may be greater than about 200° C. and less than 250° C., and the second temperature may be greater than about 70° C. and less than 200° C.

Referring to FIGS. 2 and 8, the hole transport layer 710 and the hole injection layer 720 may be sequentially formed on the emission layer 600 (S60). The hole transport layer 710 and the hole injection layer 720 may be formed through various suitable processes such as inkjet printing, vacuum deposition, spin coating, casting, LB (Langmuir-Blodgett), laser printing, and/or laser induced thermal imaging (LITI).

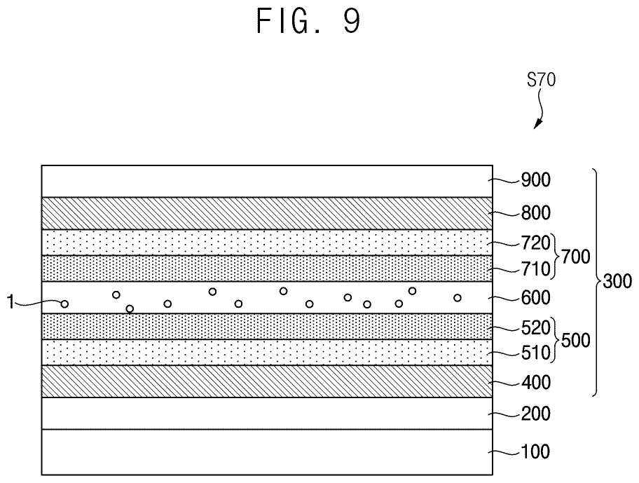

Referring to FIGS. 2 and 9, the anode 800 and the capping layer 900 may be sequentially formed on the hole injection layer 720 (S70). The anode 800 and the capping layer 900 may be deposited through various suitable processes such as chemical vapor deposition (CVD), physical vapor deposition (PVD), and/or atomic layer deposition (ALD).

In the method of manufacturing the light emitting diode 300 (S100) according to an embodiment of the present disclosure, the first emission solution 610 may be baked to form the second emission solution 620, and the second emission solution 620 may be annealed to form the emission layer 600. The first emission solution 610 may be heated in a nitrous oxide (N₂O) environment at a first temperature of greater than about 200° C. and less than about 250° C., for about 10 minutes to about 30 minutes. The second emission solution 620 may be heated at a second temperature in a range of about 70° C. and more and about 200° C., for about 5 minutes to about 20 minutes in an air environment including moisture and oxygen. An environment and the second temperature in which the second emission solution 620 is annealed may be different from an environment and a first temperature in which the first emission solution 610 is baked, respectively. As described above, the second emission solution 620 may be heated in an air environment, and the second temperature may be lower than the first temperature. As the second emission solution 620 is annealed in a relatively mild environment, the film density of the emission layer 600 may increase. Accordingly, during the formation of the hole transport layer 710, defects in film cracking and/or film tearing of the emission layer 600 may be prevented or reduced.

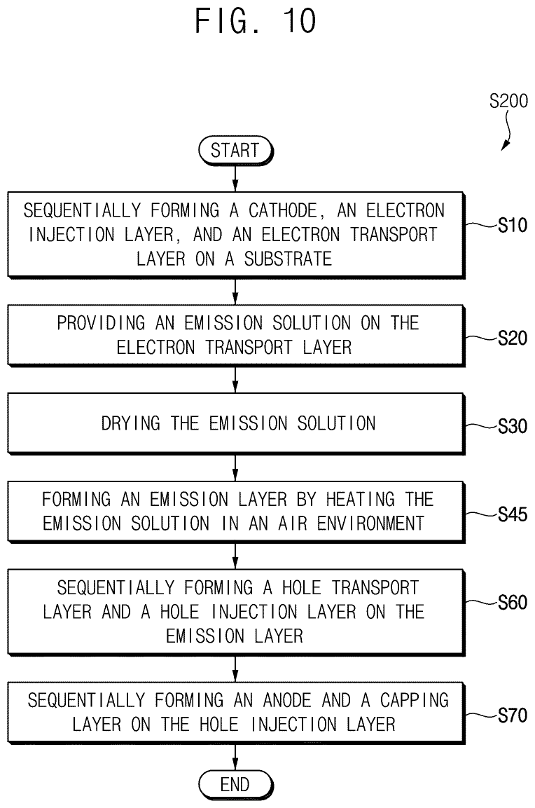

FIG. 10 is a flowchart illustrating another example of a method of manufacturing the light emitting diode of FIG. 1.

Referring to FIG. 10, in another example of the method of manufacturing the light emitting diode of FIG. 1 (S200), the cathode 400, the electron injection layer 510, and the electron transport layer 520 may be formed sequentially (S10). An emission solution may be provided on the electron transport layer 520 (S20), the emission solution may be dried (S30), and the emission solution may be heated in an air environment to form the emission layer 600 (S45). The hole transport layer 710 and the hole injection layer 720 may be sequentially formed on the emission layer 600 (S60). The anode 800 and the capping layer 900 may be formed on the hole injection layer 720 (S70).

However, another example of the manufacturing method (S200) may be substantially the same as the example of manufacturing method described above with reference to FIG. 2 (S100), except for the step (S45) of forming the emission layer 600 by heating the emission solution in an air environment.

In step S45 of forming the emission layer 600 by heating the emission solution in an air environment, the emission solution may be substantially the same as the first emission solution 610 described above with reference to FIG. 4.

The emission layer 600 may be formed by annealing the emission solution at the second temperature described above (S45). The emission solution may be heated to the second temperature in a chamber in an air environment including moisture and oxygen, and a film density of the emission solution may be increased. The second temperature may be about 70° C. to 200° C., and the emission solution may be heated for about 5 minutes to 20 minutes. In addition, the emission solution may be cooled after the heating process is finished.

Hereinafter, the effect of the present invention will be described in more detail through a comparative embodiment and embodiments of the present disclosure.

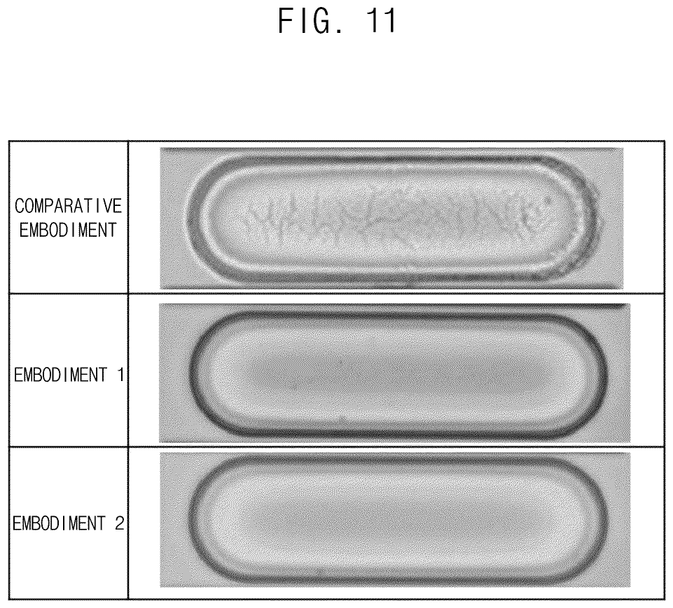

FIG. 11 is a diagram illustrating micrographs of the light emitting diode according to the comparative embodiment and embodiments of the present disclosure.

### Embodiment 1

A 15 Ω/cm2 ITO glass substrate (Corning Co.) was cut into a size of 50 mm×50 mm×0.7 mm and ultrasonically cleaned in isopropyl alcohol and pure water for 30 minutes each to prepare a transparent electrode. A film was formed on the transparent electrode by inkjet printing of 1 mL of an electron injection layer composition, 1 mL of an electron transport layer composition, and 1 mL of an emission layer composition.

In more detail, an inorganic electron transport layer composition was inkjet-printed on the cleaned transparent electrode to form a film having a thickness of 500 nm, and then baked at 200° C. for 10 minutes to form an electron transport layer.

An emission layer composition was inkjet printed on the electron transport layer to form a film having a thickness of 30 nm, and then baked at 200° C. for 10 minutes to form a preliminary emission layer. The preliminary emission layer was annealed at 140° C. for 10 minutes to form an emission layer.

A film having a thickness of 50 nm was formed by inkjet printing a hole injection layer composition and a hole transport layer composition on the emission layer. AgMg was vacuum deposited on the hole transport layer to form an anode with a thickness of 100 nm.

### Embodiment 2

After inkjet printing the emission layer composition on the electron transport layer of Embodiment 1 to form a film having a thickness of 30 nm, annealing was performed at 140° C. for 10 minutes to form an emission layer.

### Comparative Embodiment

After inkjet printing the emission layer composition on the electron transport layer of Embodiment 1 to form a film having a thickness of 30 nm, annealing was performed at 200° C. for 10 minutes to form an emission layer.

As shown in FIG. 11, it was confirmed that film cracking defects and/or film tearing defects of the emission layer occurred in the light emitting diode according to the comparative embodiment. On the other hand, it was confirmed that film cracking defects and/or film tearing defects were prevented or reduced in the light emitting diodes according to Embodiments 1 and 2.

Although certain embodiments and implementations have been described herein, other embodiments and modifications will be apparent from this description. Accordingly, the present disclosure is not limited to such embodiments, but rather the scope of the present disclosure is defined by the scope of the appended claims and various obvious modifications and equivalent arrangements as would be apparent to a person of ordinary skill in the art.

What is claimed is:

1. A method of manufacturing a light emitting diode, the method comprising:
forming a first auxiliary layer on a substrate;
providing a first emission solution comprising a quantum dot, on the first auxiliary layer;
forming a second emission solution by heating the first emission solution to a first temperature;
forming an emission layer by heating the second emission solution to a second temperature lower than the first temperature; and
forming a second auxiliary layer on the emission layer.

2. The method of claim 1, wherein the second emission solution is annealed at the second temperature.

3. The method of claim 1, wherein the first temperature is greater than 200° C. and less than 250° C., and
the second temperature is about 70° C. or more and 200° C. or less.

4. The method of claim 1, wherein the first emission solution is heated in a nitrous oxide (N₂O) environment, and
the second emission solution is heated in an air environment.

5. The method of claim 4, wherein the air environment comprises moisture and oxygen.

6. The method of claim 1, wherein the first emission solution is heated for about 10 minutes to 30 minutes, and
the second emission solution is heated for about 5 minutes to 20 minutes.

7. The method of claim 1, wherein the quantum dot comprises nanoparticles, and
each of the nano particles comprises a core comprising a first semiconductor material and a shell comprising a second semiconductor material.

8. The method of claim 7, wherein the first semiconductor material and the second semiconductor material each independently comprise at least one selected from the group consisting of InP, ZnSe, and ZnS.

9. The method of claim 1, wherein the forming the first auxiliary layer comprises:
forming an electron injection layer on the substrate; and
forming an electron transport layer on the electron injection layer.

10. The method of claim 1, wherein the forming the second auxiliary layer comprises:
forming a hole transport layer on the emission layer; and
forming a hole injection layer on the hole transport layer.

11. The method of claim 1, further comprising:
forming a cathode on the substrate; and
forming an anode on the second auxiliary layer.

12. The method of claim 11, further comprising:
forming a capping layer on the anode.

13. The method of claim 1, wherein the first emission solution is provided through an inkjet printing method.

14. A method of manufacturing a light emitting diode, the method comprising:
forming a first auxiliary layer on a substrate;
providing a first emission solution comprising a quantum dot on the first auxiliary layer;
forming a second emission solution by heating the first emission solution;
forming an emission layer by heating the second emission solution in an air environment; and
forming a second auxiliary layer on the emission layer.

15. The method of claim 14, wherein the second emission solution is annealed in the air environment.

16. The method of claim 14, wherein the first emission solution is heated in a nitrous oxide (N₂O) environment, and
The air environment comprises moisture and oxygen.

17. The method of claim 14, wherein the first emission solution is heated to a first temperature, and
the second emission solution is heated a second temperature lower than the first temperature.

18. A method of manufacturing a light emitting diode, the method comprising:
forming a first auxiliary layer on a substrate;
providing an emission solution comprising a quantum dot on the first auxiliary layer;
forming an emission layer by heating the emission solution in an air environment; and
forming a second auxiliary layer on the emission layer.

19. The method of claim 18, wherein the air environment comprises moisture and oxygen.

20. The method of claim 18, wherein the emission solution is heated for about 5 minutes to 20 minutes at about 70° C. or more and 200° C. or less.
